(19) United States
(12) Patent Application Publication
(10) Pub. No.: US 2009/0189233 A1
(43) Pub. Date: Jul. 30, 2009

(54) CMOS IMAGE SENSOR AND METHOD FOR MANUFACTURING SAME

(75) Inventors: Jen-Cheng Liu, Hsin-Chu City (TW); Dun-Nian Yaung, Taipei City (TW); Shou-Gwo Wuu, Hsin-Chu City (TW); Chi-Hsin Lo, Zhubei City (TW); Feng-Jia Shiu, Jhudong Township (TW); Chung-Yi Yu, Hsin-Chu (TW)

Correspondence Address: DUANE MORRIS LLP (TSMC);IP DEPARTMENT, 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 12/020,149

(22) Filed: Jan. 25, 2008

(51) Int. Cl. H01L 31/0232; H01L 31/18

(52) U.S. Cl. 257/432; 438/70; 257/E31.127

(57) ABSTRACT

An optical image sensor is fabricated by forming a pixel array and a peripheral region surrounding the pixel array on a semiconductor substrate, the peripheral region containing peripheral circuitry. An inter-level-dielectric layer is formed over the substrate and a plurality of interconnect wiring layers are formed over the inter-level-dielectric layer. Each interconnect wiring layer includes interconnecting metal features and a layer of inter-level-dielectric material covering the interconnecting metal features. The plurality of interconnect wiring layers are provided in a manner that there are N levels of wiring layers in the peripheral region and 1 to (N−1) levels of wiring layers over the pixel array. An etch-stop layer is formed over the top-most level interconnecting metal features in the peripheral region.

### FIELD OF THE INVENTION

The present disclosure relates to image sensor devices such as CMOS (complementary-metal-oxide-semiconductor) or CCD image sensor devices and methods for fabricating the same.

### BACKGROUND

Image sensors such as CMOS or CCD images sensor devices are used in a variety of applications such as digital cameras. These devices utilize an array of active pixels or image sensor cells, comprising photodiode elements, to collect light energy for conversion of images to digital data streams. The structure of the image sensor devices are configured with an array of photodiode elements forming the pixel array that is surrounded by ASIC circuitry in the periphery of the pixel array region providing the circuitry for logic control and decoding, etc.

In conventional methods for fabricating these image sensors, the interconnect wiring structures above the pixel array region tend to be too thick and the resulting long incident path for the light reduces optical efficiency of the image sensors. The conventional methods also produce structures above the pixel array region that are not uniform in thickness throughout the pixel array. This non-uniformity in thickness of the structures above pixel array results in the image sensors having inherent optical aberration defects. Thus, an improved image sensor device and methods of fabricating the same are needed.

### SUMMARY

According to an embodiment, a method for fabricating optical image sensors is disclosed. The method comprises forming a pixel array and a peripheral region surrounding the pixel array on a semiconductor substrate, said peripheral region containing peripheral circuitry. A first inter-level-dielectric layer is formed over the substrate. Then, a plurality of interconnect wiring layers are formed over the first inter-level-dielectric layer, each interconnect wiring layer comprising interconnecting metal features, wherein N levels of interconnect wiring layers are provided over the peripheral region and 1 to (N−1) levels of interconnect wiring layers are provided over the pixel array, whereby the N levels of interconnect wiring layers over the peripheral region has a top-most level interconnecting metal features. A dielectric passivation layer is formed over the plurality of interconnect wiring layers and the dielectric passivation layer is planarized and then etched back down to the top-most level interconnecting metal features over the peripheral region. Next, a photoresist mask is formed over the dielectric passivation layer wherein the photoresist mask covers the dielectric passivation layer over the peripheral region and exposes the dielectric passivation layer over the pixel array. With the aid of the photoresist mask, the dielectric passivation layer and at least a portion of the interconnect wiring layers over the pixel array are removed.

According to another embodiment, a method for fabricating optical image sensors comprises forming a pixel array and a peripheral region surrounding the pixel array on a semiconductor substrate, said peripheral region containing peripheral circuitry and forming a first inter-level-dielectric layer over the substrate. A plurality of interconnect wiring layers are formed over the first inter-level-dielectric layer, each interconnect wiring layer comprising interconnecting metal features, wherein N levels of interconnect wiring layers are provided over the peripheral region and 1 to (N−1) levels of interconnect wiring layers are provided over the pixel array, whereby the N levels of interconnect wiring layers over the peripheral region has a top-most level interconnecting metal features. An etch-stop layer is then formed over the top-most level interconnecting metal features, wherein surface of the etch-stop layer over the pixel array is substantially planar. A dielectric passivation layer is formed over the etch-stop layer and a photoresist mask is formed over the dielectric passivation layer wherein the photoresist mask covers the dielectric passivation layer over the peripheral region and exposes the dielectric passivation layer over the pixel array. Then with the aid of the photoresist mask, the dielectric passivation layer over the pixel array is removed down to the etch stop layer by a first removal process. Next, the etch-stop layer and at least a portion of the interconnect wiring layers over the pixel array are removed by a second removal process, whereby the interconnect wiring layers over the pixel array region has a top surface that is substantially planar.

According to another embodiment an optical image sensor device is disclosed. The device comprises a substrate, a pixel array and a peripheral region formed on the substrate, where the peripheral region contains peripheral circuitry. An inter-level-dielectric layer is provided over the pixel array and the peripheral region. Over the inter-level dielectric layer is a plurality of interconnect wiring layers, each interconnect wiring layer comprising interconnecting metal features, wherein N levels of interconnect wiring layers are provided over the peripheral region and 1 to (N−1) levels of interconnect wiring layers are provided over the pixel array.

By removing the dielectric passivation layer over the pixel array and further reducing the thickness of the interconnect wiring layers over the pixel array, the length of the incident path of light to the pixel array is reduced and the use of the etch-stop layer the top-most level of interconnect metal features minimizes thickness variation of the structures over the pixel array region, thus minimizing or eliminating optical aberrations.

### BRIEF DESCRIPTION OF THE DRAWINGS

FIGS. 1-8 are cross-sectional illustrations showing a method of fabricating an image sensor device and the structure of the device according to a first embodiment of the present disclosure.

FIGS. 9-14 are cross-sectional illustrations showing a method of fabricating an image sensor device and the structure of the device according to a second embodiment of the present disclosure.

FIGS. 15-18 are cross-sectional illustrations showing a method of fabricating an image sensor device and the structure of the device according to a third embodiment of the present disclosure.

FIGS. 19-21 are cross-sectional illustrations showing a method of fabricating an image sensor device and the structure of the device according to a fourth embodiment of the present disclosure.

The features shown in the above referenced drawings are illustrated schematically and are not intended to be drawn to scale nor are they intended to be shown in precise positional relationship. Like reference numbers indicate like elements.

### DETAILED DESCRIPTION

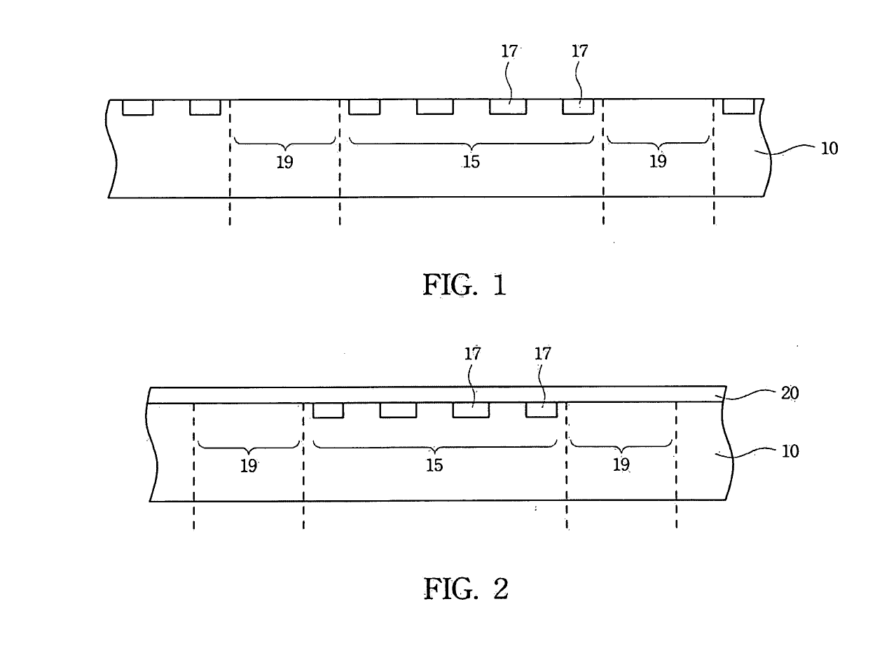

Referring to FIGS. 1-10 an optical image sensor device and a method for fabricating such optical image sensor device according to a first embodiment will be disclosed. A pixel array 15 of pixel elements 17 is formed on a semiconductor substrate 10. The pixel elements 17 can be CCD or CMOS based photo devices and can be active type or passive type. Such pixel elements 17 can be active or passive sensor types and can comprise 3T CMOS image sensors, 4T CMOS image sensors, transfer transistor, reset transistor, source follower transistor and select transistor, pinned photodiodes or non-pinned photodiodes. The pixel elements can also comprise MOSFET devices containing metal silicide at both source/drain only. The processes for forming photodiodes on semiconductor substrate 10 to form pixels based on CMOS or CCD are well known in the art and the details of the photodiode circuitry nor the details of the fabrication process for forming the pixel elements 17 will not be discussed here.

Surrounding the pixel array 15 is a peripheral region 19 that contains peripheral circuitry, usually ASIC logic control circuitry for controlling the functions of the pixel photodiodes 17 in the pixel array 15. Such logic control circuits may comprise MOSFET devices containing metal silicide at both source/drain and gate electrode.

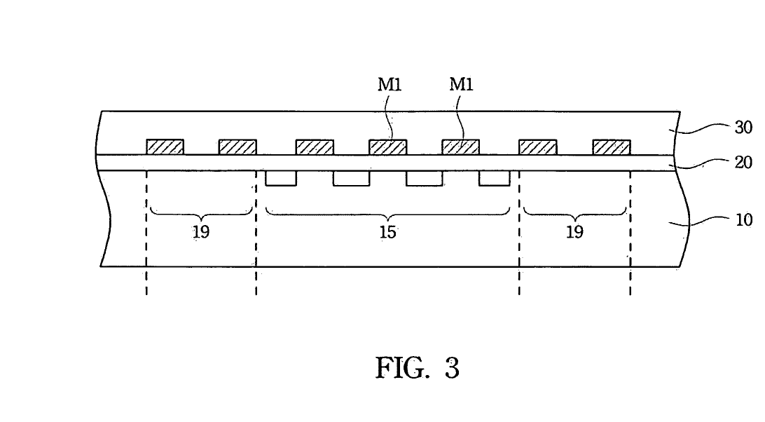

Referring to FIG. 2, an inter-level-dielectric (ILD) layer 20 is formed over the substrate 10 and covers the pixel array 15 as well as the peripheral region 19. Referring to FIG. 3, an interconnect wiring layer is formed over the ILD layer 20. The interconnect wiring layer comprises interconnecting metal features M1 and an ILD layer 30 covering the interconnecting metal features M1.

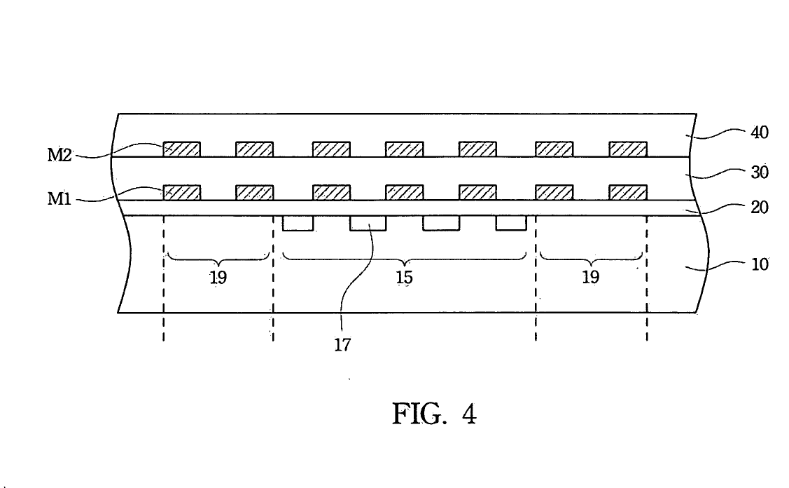

Next, referring to FIG. 4, a second interconnect wiring layer is formed over the first wiring layer. The second interconnect wiring layer comprises interconnecting metal features M2 and an ILD layer 40 covering the interconnecting metal features M2. The ILD layers 20, 30 and 40 can be regular-k, low-k or extremely low-k dielectric materials well known in the semiconductor processing technology. Typically, ILD layer 20 includes doped silicon oxide like PSG. The ILD layer 30 or ILD 40 includes silicon oxide formed by PECVD with thickness from about 150 nm to 600 nm.

In this illustrative example, two interconnect wiring layers are shown, the two wiring layers comprising interconnecting metal features M1, M2 and respective ILD layers 30 and 40 covering the interconnecting metal features. However, the actual number of interconnect wiring layers will depend upon the particular design of the image sensor device and its requirements. But, an image sensor device of this disclosure will comprise at least one interconnect wiring layer over the pixel array 15, each interconnect wiring layer comprising interconnecting metal features and a layer of ILD material covering the interconnecting metal features. The interconnecting metal features M1, M2 are aligned and positioned between the photodiodes 17 of the pixel array 15 as shown to minimize any obstruction to the incident light path down to the photodiodes 17.

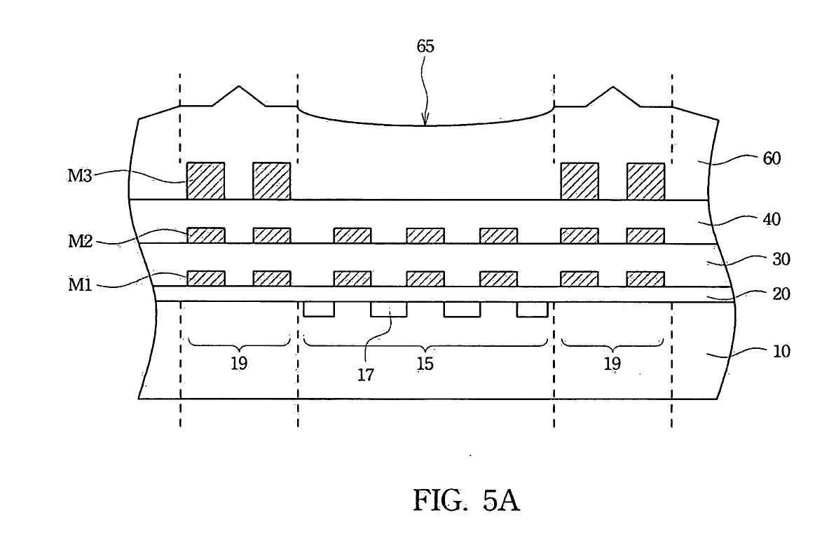

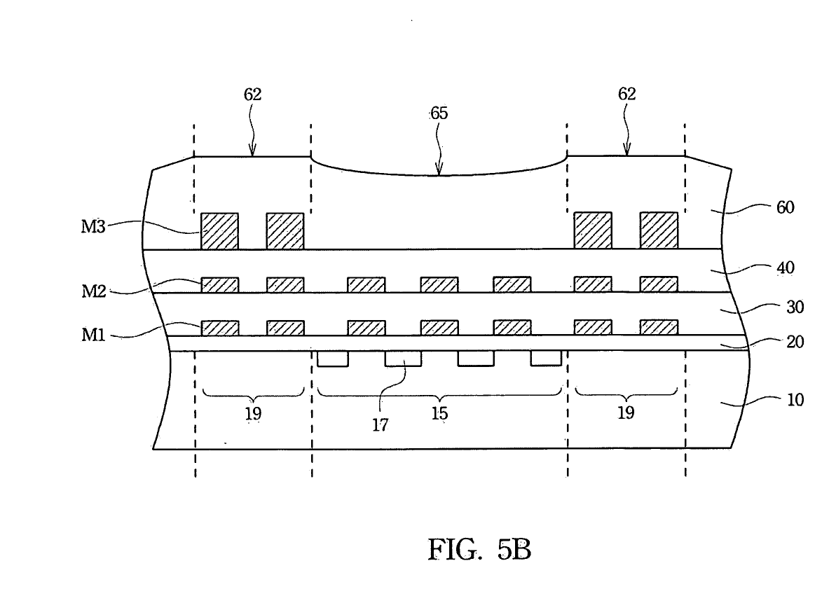

Referring to FIG. 5, next, a top-most level interconnecting metal features M3 are formed on top of the at least one interconnect wiring layers over the peripheral region 19. Because the top-most level interconnecting metal features M3 are provided over the peripheral region 19 only, the area over the pixel array 15 is substantially devoid of the top-most level interconnecting metal features M3. This aspect of the invention provides the additional wiring capabilities provided by the top-most level interconnecting metal features M3 without adding additional optical obstructions above the pixel array 15 that would obstruct the incident light and also increase the overall thickness of the wiring layers over the pixel array 15. The metal features M1, M2 and M3 can be aluminum-based material or copper-based material. Typically, the metal features M1, M2 and M3 are formed by plasma etching if they are aluminum-based material. The metal features M1, M2 and M3 are formed by damascene technique if they are copper-based material.

The total number N of wiring or interconnecting metal levels required for the image sensor device will depend upon the particular design for the image sensor device. However, according to an aspect of the invention, at least the top-most level interconnecting metal features, M3 in the illustrated examples, are placed in the peripheral region 19 only while anywhere from 1 to (N−1) levels of the remaining lower level interconnecting metal features can reside over the pixel array 15. Thus, there will always be at least one fewer level of interconnecting metal features over the pixel array 15 compared to the peripheral region 19. This applies to all embodiments discussed in this disclosure.

Continuing with the example shown in FIG. 5A, an ILD layer 60 is formed over the metal features M3 and the ILD layer 40. The ILD layer 60 can be an oxide layer formed of PECVD silicon oxide with thickness from about 100 nm to 600 nm.

Because of the presence of the interconnecting metal features M3 in the peripheral region 19, the surface of the ILD layer 60 follows the topology and generally the surface 65 of the ILD layer 60 over the pixel array 15 is non-planar and has a generally concave contour as shown in FIG. 5A. This contour results in the center of the surface 65 over the pixel array 15 being lower than the surface of the ILD layer 60 over the peripheral region 19.

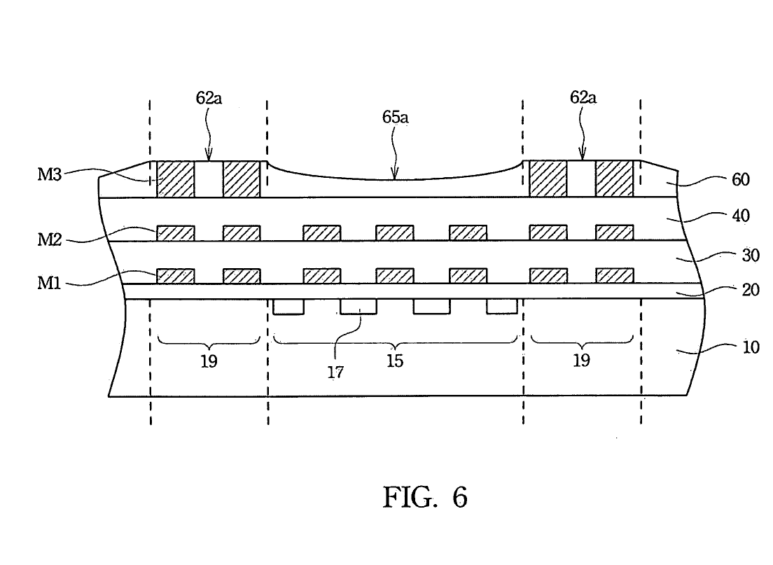

Referring to FIG. 5B, the ILD layer 60 can be polished by chemical mechanical polishing (CMP) to planarize the top surface 62 of the ILD layer 60 over the peripheral region 19. Next, referring to FIG. 6, the ILD layer 60 is etched back using plasma etching until the surface 62a of the ILD layer 60 over the peripheral region is lowered down to the top surface of the metal features M3. Because plasma etching removes material uniformly, the surface 65 of the ILD layer 60 over the pixel array 15 is also etched down to a lower surface 65a. The contour of the lowered surface 65a replicates the original surface 65.

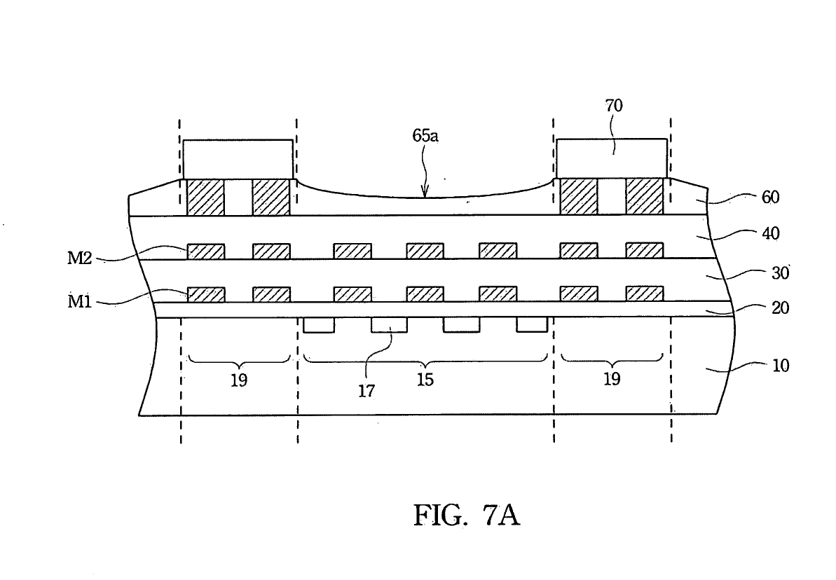

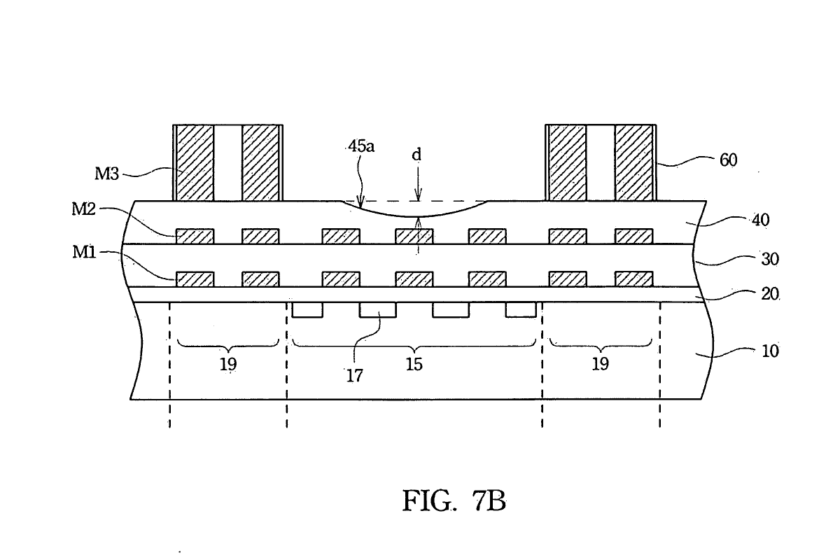

Referring to FIG. 7A, after the CMP planarization and etch back of the ILD layer 60, a photoresist layer is applied over the ILD layer 60 and is selectively patterned into a mask 70. The photolithography process for forming the photoresist mask 70 is well known in the art and need not be discussed here in detail. The photoresist mask 70 exposes only the area over the pixel array 15 and allows selectively removing the ILD layer 60 over the pixel array 15. The CMP planarization of the ILD layer 60 is optional depending upon the particular process requirement, however, and according to another embodiment, the photoresist mask 70 can be formed over the non-planarized ILD layer 60 shown in FIG. 5A.

Next, with the photoresist mask 70 in place, the ILD layer 60 over the pixel array 15 is removed by a plasma etching process utilizing a plasma containing fluorine-based chemistry such as CH₄ & CHF₃. The plasma etching can be isotropic etching mode or anisotropic etching mode. As shown in FIG. 7B, because plasma etching removes material uniformly, when the ILD layer 60 over the pixel array 15 is removed down to the underlying ILD layer 40, the concave contour of the surface 65a of the ILD layer 60 is maintained and at least a portion of the ILD layer 40 is also removed. As a result the surface of the ILD layer 40 over the pixel array 15 ends up with a concave surface 45a replicating the concave surface 65a of the ILD layer 60. The concave surface 45a of the ILD layer 40 lowers the thickness of the ILD layer 40 by at least 100 nm denoted by d in FIG. 7B. The photoresist mask 70 is then removed.

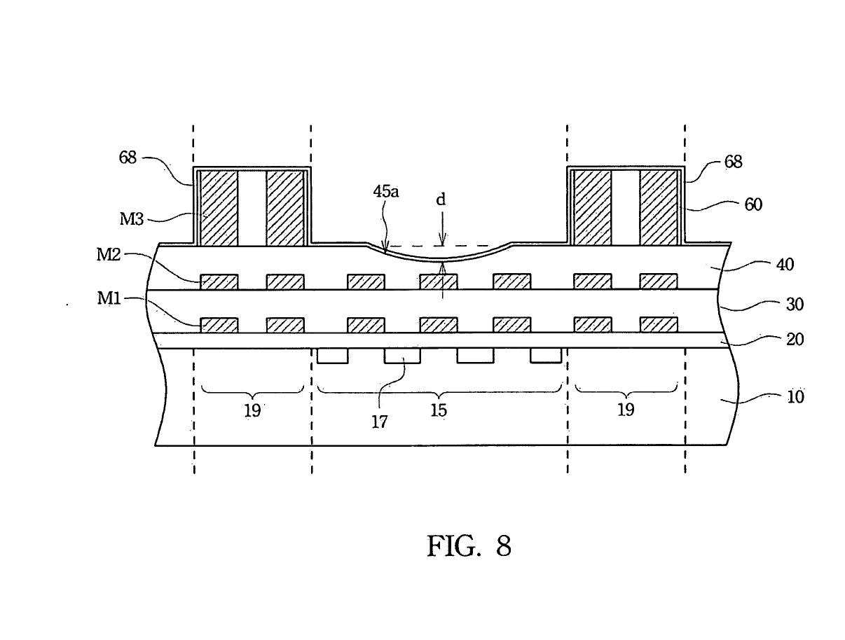

Referring to FIG. 8, after the photoresist mask 70 is removed, a layer of silicon nitride 68 is deposited over the pixel array 15 and the peripheral region 19 covering the structure shown in FIG. 7B to protect underlying optical image sensor device. The silicon nitride layer 68 prevent the underlying structures from particulate and moisture contamination. In order to let incident light reach the pixel array 15, the silicon nitride layer 68 has to be optically transparent. To be optically transparent, the thickness of the silicon nitride layer 68 is less than about 100 nm and preferably less than about 60 nm. After formation of silicon nitride layer 68, a plurality of color filters and micro-lenses (not shown) may be formed over silicon nitride layer 68 over the pixel array 15. The silicon nitride layer 68 can be formed by a plasma-enhanced chemical vapor deposition (PECVD) process.

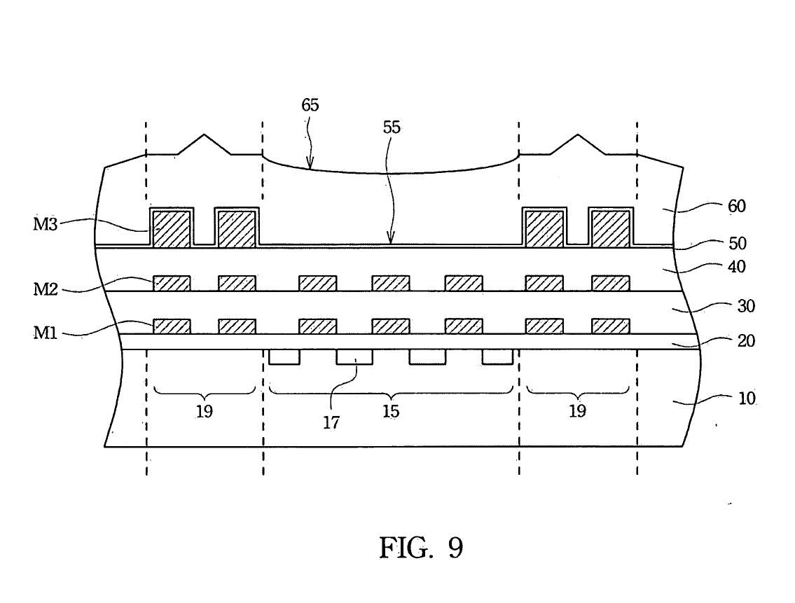

Referring to FIG. 9, according to a second embodiment, after the top-most level interconnecting metal features M3 are formed on top of the at least one interconnect wiring layers over the peripheral region 19, an etch-stop layer 50 is formed overlying the top-most level interconnecting metal features M3. The etch-stop layer 50 can be such commonly used etch-stop material such as silicon nitride, silicon oxynitride or carbon-containing material such as silicon carbide. The etch-stop layer 50 is about 10 nm-100 nm thick. The surface 55 of the etch-stop layer 50 over the pixel array 15 is substantially planar mimicking the topology of the ILD layer 40 below. Next, a ILD layer 60 is formed over the etch-stop layer 50. Because of the presence of the interconnecting metal features M3 in the peripheral region 19, the ILD layer 60 follows the topology and generally the surface 65 of the ILD layer 60 over the pixel array 15 is non-planar and has a generally concave contour as shown in FIG. 5. This contour results in the center of the surface 65 over the pixel array 15 being lower than the surface of the ILD layer 60 over the peripheral region 19.

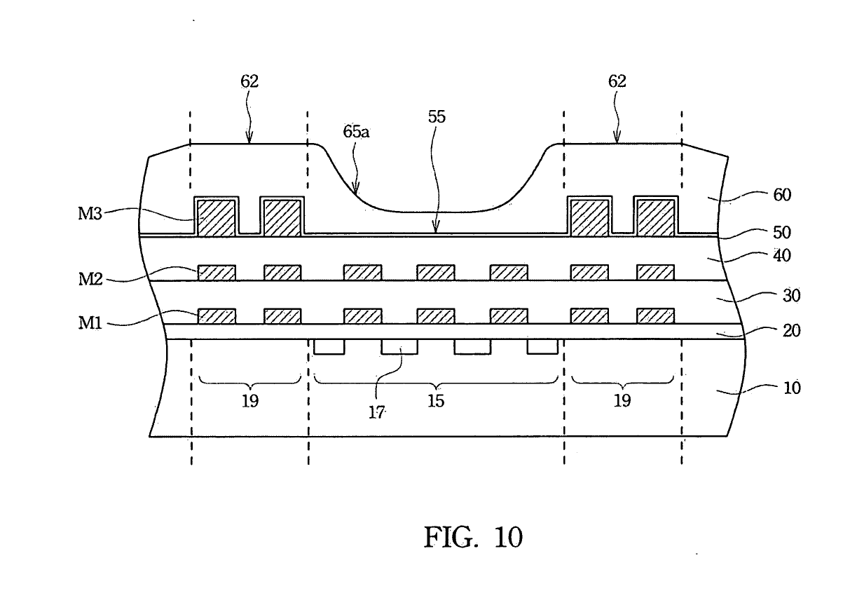

Referring to FIG. 10, the ILD layer 60 can be CMP polished to planarize the top surface 62 of the ILD layer 60 over the peripheral region 19. The CMP process removes material from the surface of the ILD layer 60 across the board and the surface 65 of the ILD layer 60 over the pixel array 15 is further lowered to surface 65a.

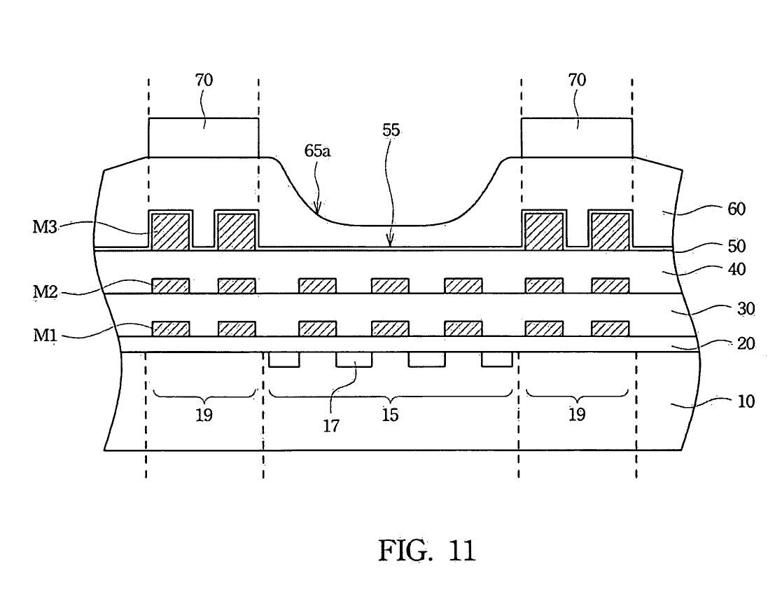

Referring to FIG. 11, after the CMP planarization, a photoresist layer is applied over the ILD layer 60 and is selectively patterned into a mask 70. The photolithography process for forming the photoresist mask 70 is well known in the art and need not be discussed here in detail. The photoresist mask 70 exposes only the area over the pixel array 15 and allows selectively removing the ILD layer 60 over the pixel array 15. The CMP process is optional depending upon the particular process requirement, however, and according to another embodiment, the photoresist mask 70 can be formed over the non-planarized ILD layer 60 shown in FIG. 9.

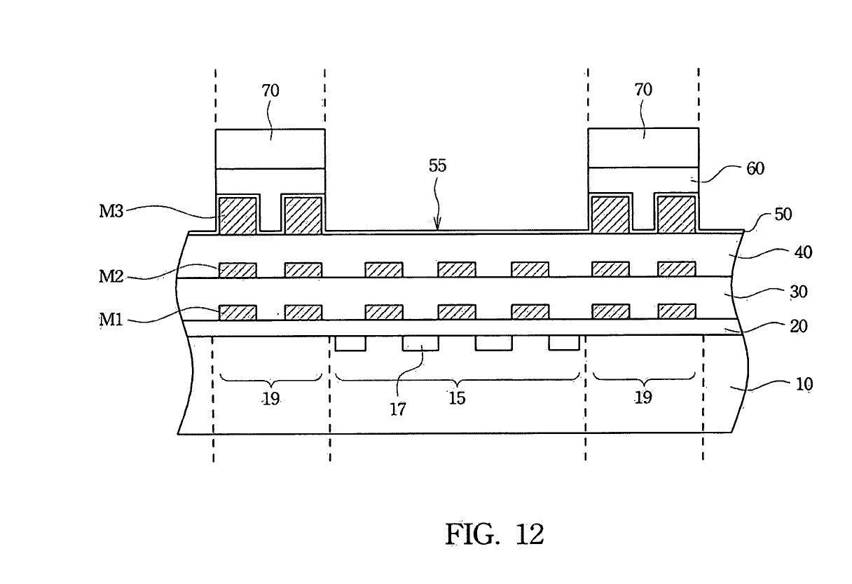

Referring to FIG. 12, with the photoresist mask 70 in place, the ILD layer 60 over the pixel array 15 is then removed down to the etch stop layer 50 by a plasma etching process using a plasma containing fluorine-based chemistry such as CH₄ & CHF₃. The plasma etching can be isotropic etching mode or anisotropic etching mode. Once all ILD layer 60 over the pixel array 15 is removed down to the etch-stop layer 50, the substantially planar surface 55 of the etch-stop layer 50 is left.

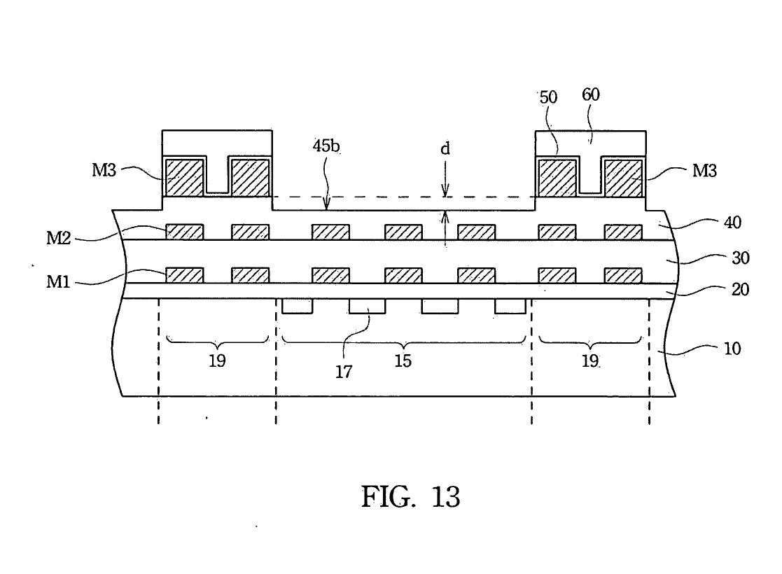

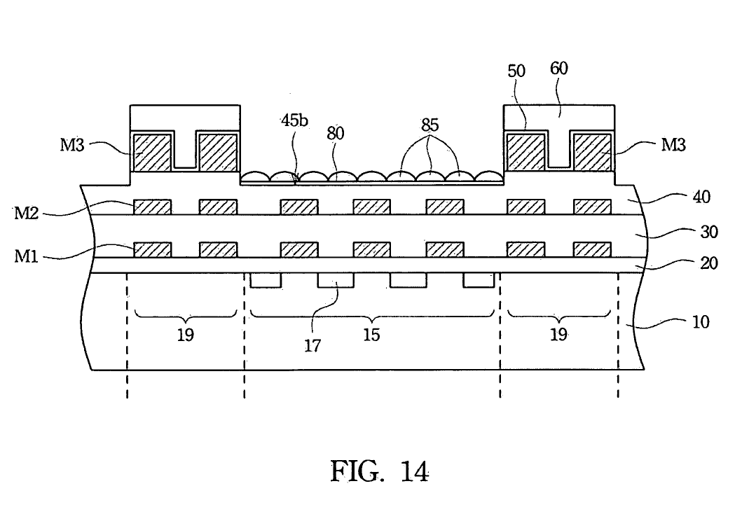

Referring to FIG. 13, the plasma etching process is continued until the etch-stop layer 50 over the pixel array 15 is removed and at least a portion of the ILD layer 40 is also removed. The thickness of the ILD layer 40 over the pixel array 15 is reduced by a predetermined thickness d of at least 100 nm. Because a uniformly etching dry etching process such as plasma etching maintains the surface contour of the material being etched, the substantially planar surface 55 of the etch-stop layer 50 is retained and the resulting surface 45b of the ILD layer 40 over the pixel array 15 after the plasma etching process is also substantially planar. Thus, the provision of the etch-stop layer 50 over the M3 wiring level prevents the non-planar contour of the surface 65 of the ILD layer 60 being replicated and allows formation of the substantially planar surface 45b over the pixel array 15. After the plasma etching, the photoresist mask 70 is removed. As shown in FIG. 14, at this point, a plurality of color filters 80 and micro-lenses 85 may be formed on the surface 45b of the ILD layer 40 over the pixel array 15.

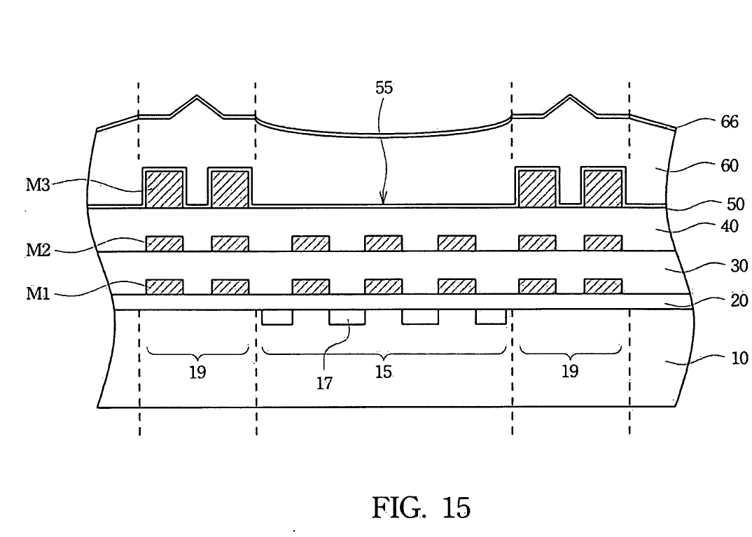

Referring to FIG. 15, according to a third embodiment, after the structure shown in FIG. 9 is formed, a layer of silicon nitride 66 is formed overlying the ILD layer 60, the silicon nitride layer 66 is similar to the silicon nitride layer 68 in the embodiment of FIGS. 9-14 and is an optically transparent material and the combination of layers 60 and 66 serves as a protection/passivation layer 60/66.

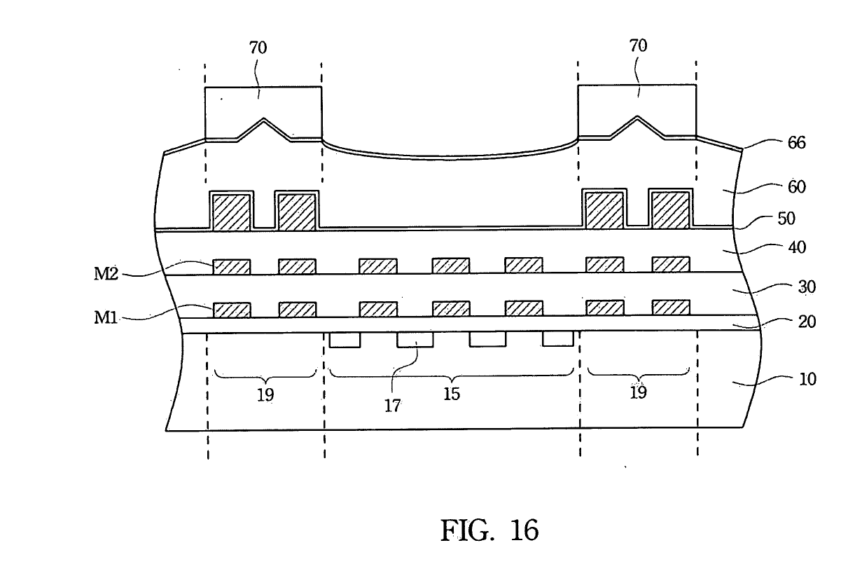

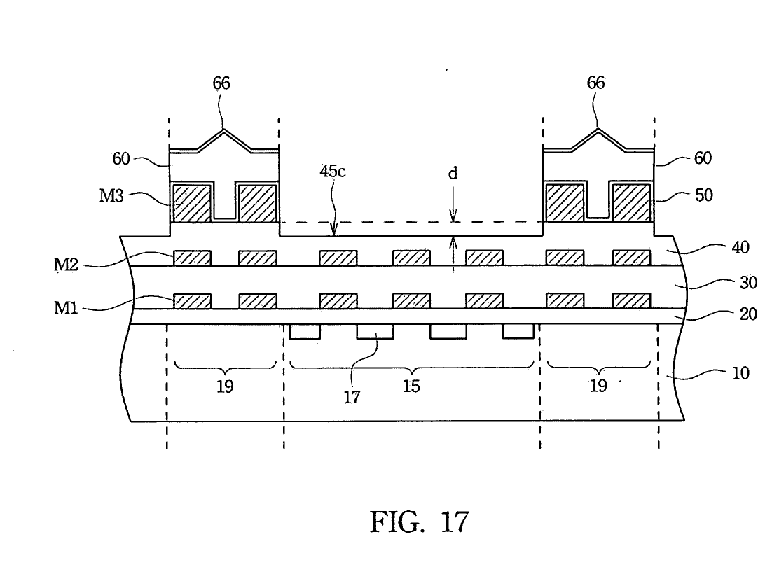

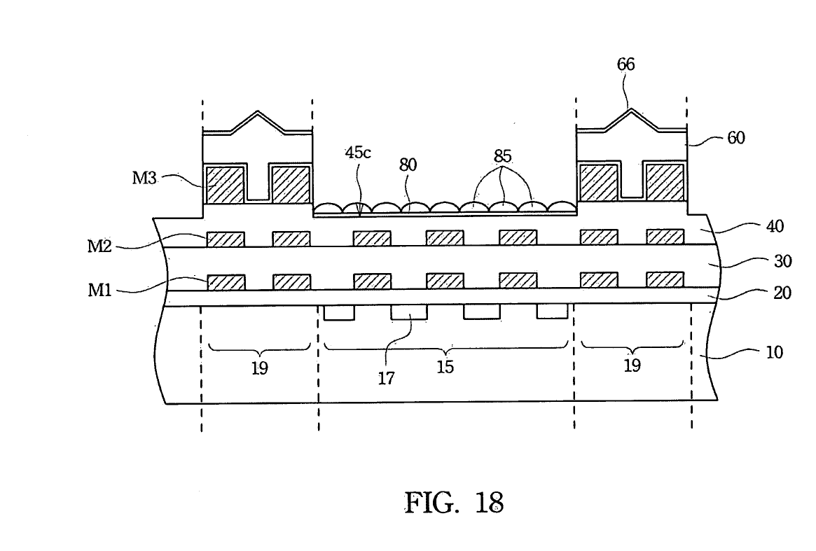

Referring to FIG. 16, a photoresist mask 70 is then formed over the protection/passivation layer 60/66 by selective pattern photolithography process to expose only the area over the pixel array 15. Referring to FIG. 17, the exposed areas over the pixel array 15 are then etched by plasma etching to remove the second etch-stop layer 150, the protection/passivation layer 60/66, the first etch-stop layer 50 and at least a portion of the ILD layer 40. In the final structure achieved, by etching away at least a portion of the ILD layer 40, the surface 45c of the ILD layer 40 over the pixel array 15 is lowered by a predetermined thickness d of at least 100 nm. Lastly, as shown in FIG. 18, a plurality of color filters 80 and a plurality of micro-lenses 85 can be formed on the surface 45c of the ILD layer 40 over the pixel array 15.

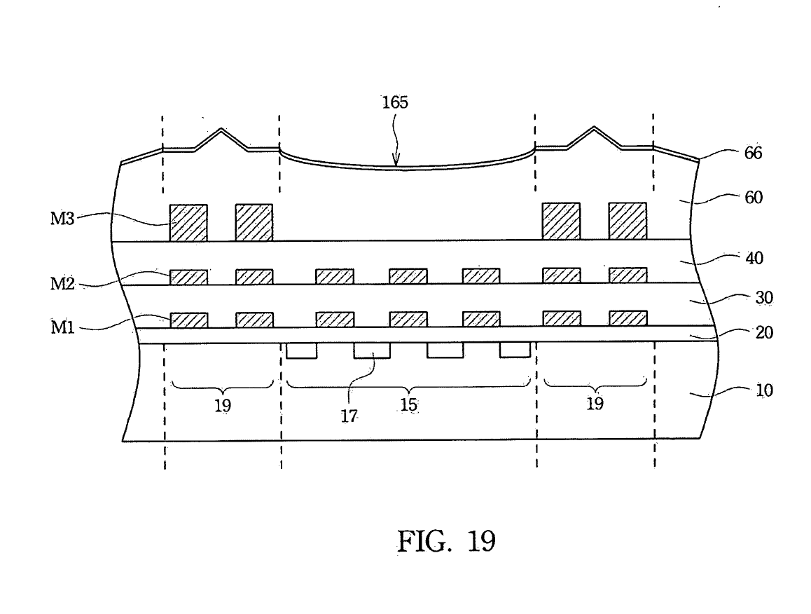

Referring to FIG. 19, according to a fourth embodiment, after the structure of FIG. 5A is formed, a silicon nitride layer 66 is formed overlying the ILD layer 60 resulting in a protection/passivation layer 60/66 over the metal features M3.

Because of the presence of the interconnecting metal features M3 in the peripheral region 19, the surface of the protection/passivation layer 60/66 follows the topology and generally the surface 165 of the protection/passivation layer 60/66 over the pixel array 15 is non-planar and has a generally concave contour as shown in FIG. 19. This contour results in the center of the surface 165 over the pixel array 15 being lower than the surface of the protection/passivation layer 60/66 over the peripheral region 19.

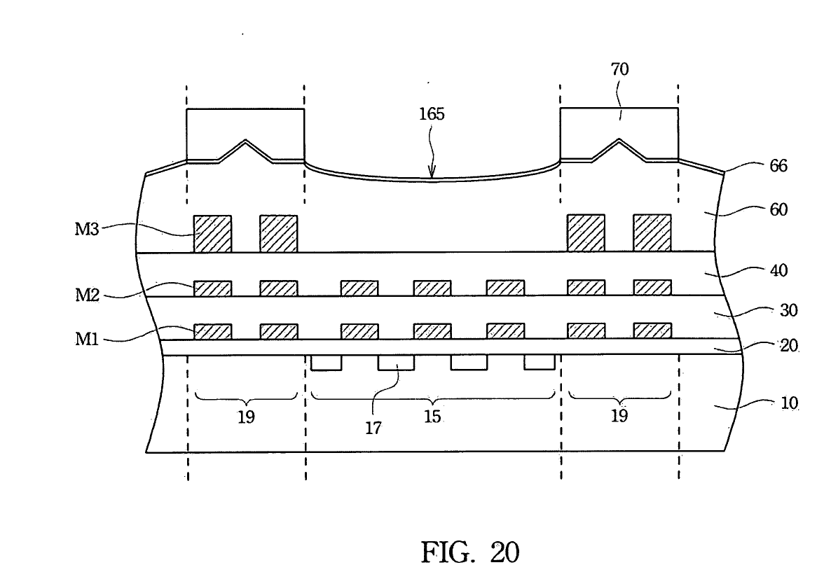

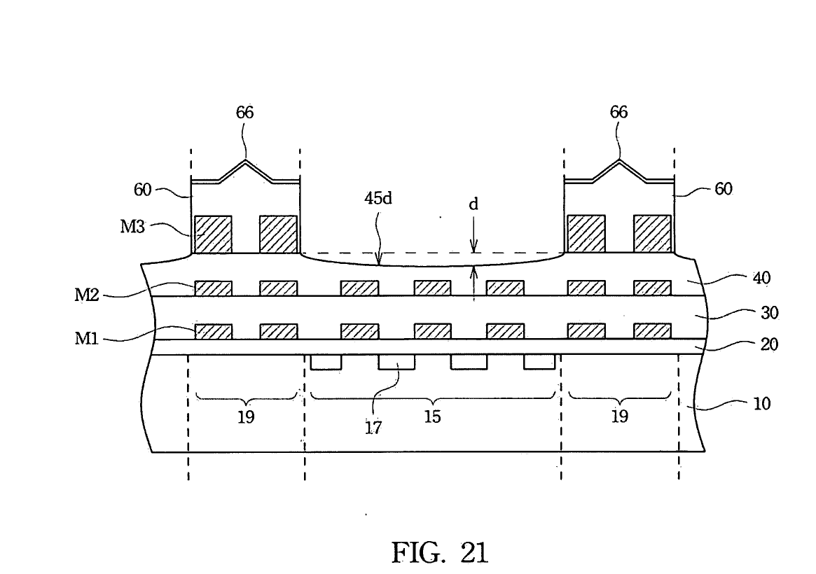

Referring to FIG. 20, a photoresist mask 70 is then formed over the layer 60/66 by selective pattern photolithography process to expose only the area over the pixel array 15. Referring to FIG. 21, the exposed protection/passivation layer 60/66 and at least a portion of the ILD layer 40 over the pixel array 15 is then removed by plasma etching. In the final structure achieved, by etching away at least a portion of the ILD layer 40, the surface 45d of the ILD layer 40 over the pixel array 15 is lowered by a predetermined thickness d of at least 100 nm. Lastly, as with the other embodiments, a plurality of color filters and a plurality of micro-lenses can be formed on the surface 45d of the ILD layer 40 over the pixel array 15.

The image sensor device and the methods for fabricating thereof described in this disclosure are only examples. The full scope of the invention described herein is to be defined by the claims provided below.

What is claimed is:

1. A method for fabricating optical image sensors comprising:
forming a pixel array and a peripheral region surrounding the pixel array on a semiconductor substrate, said peripheral region containing peripheral circuitry;
forming a first inter-level-dielectric layer over the substrate;
forming a plurality of interconnect wiring layers over the first inter-level-dielectric layer, each interconnect wiring layer comprising interconnecting metal features, wherein N levels of interconnect wiring layers are provided over the peripheral region and 1 to (N−1) levels of interconnect wiring layers are provided over the pixel array, whereby the N levels of interconnect wiring layers over the peripheral region has a top-most level interconnecting metal features;
forming a top inter-level-dielectric layer over the plurality of interconnect wiring layers;
forming a photoresist mask over the top inter-level-dielectric layer wherein the photoresist mask covers the top inter-level-dielectric layer over the peripheral region and exposes the top inter-level-dielectric layer over the pixel array; and
removing the top inter-level-dielectric layer and at least a portion of the interconnect wiring layers over the pixel array.

2. The method of claim 1, further comprising:
planarizing the top inter-level-dielectric layer; and
etching back the top inter-level-dielectric layer down to the top most level interconnecting metal features over the peripheral region.

3. The method of claim 1, further comprising:
forming an etch-stop layer overlying the top-most level interconnecting metal features before forming the top inter-level-dielectric layer, wherein surface of the etch-stop layer over the pixel array is substantially planar; and
removing the etch-stop layer over the pixel array while removing the top inter-level-dielectric layer and at least a portion of the interconnect wiring layers over the pixel array, whereby the interconnect wiring layers over the pixel array region has a top surface that is substantially planar.

4. The method of claim 1, further comprising forming an optically transparent silicon nitride passivation layer over the peripheral region and pixel array.

5. The method of claim 1, wherein the top inter-level-dielectric layer comprises an oxide layer formed with PECVD silicon oxide.

6. The method of claim 1, wherein the removal of the top inter-level-dielectric layer and at least a portion of the at least one interconnect wiring layers over the pixel array comprises plasma etching.

7. The method of claim 1, further comprising forming a plurality of color filters over the pixel array after the top inter-level-dielectric layer and at least a portion of the inter-level-dielectric layer over the pixel array are removed.

8. The method of claim 7, further comprising forming a plurality of micro-lenses over the color filters.

9. A method for fabricating optical image sensors comprising:
forming a pixel array and a peripheral region surrounding the pixel array on a semiconductor substrate, said peripheral region containing peripheral circuitry;
forming a first inter-level-dielectric layer over the substrate;
forming a plurality of interconnect wiring layers over the first inter-level-dielectric layer, each interconnect wiring layer comprising interconnecting metal features, wherein N levels of interconnect wiring layers are provided over the peripheral region and 1 to (N−1) levels of interconnect wiring layers are provided over the pixel array, whereby the N levels of interconnect wiring layers over the peripheral region has a top-most level interconnecting metal features;
forming an etch-stop layer over the top-most level interconnecting metal features, wherein surface of the etch-stop layer over the pixel array is substantially planar;
forming a top inter-level-dielectric layer overlying the etch-stop layer;
forming a photoresist mask over the top inter-level-dielectric layer wherein the photoresist mask covers the top inter-level-dielectric layer over the peripheral region and exposes the top inter-level-dielectric layer over the pixel array;
removing the top inter-level-dielectric layer over the pixel array down to the etch stop layer by a first removal process; and
removing the etch-stop layer and at least a portion of the interconnect wiring layers over the pixel array by a second removal process, whereby the interconnect wiring layers over the pixel array region has a top surface that is substantially planar.

10. The method of claim 9, wherein the inter-level-dielectric layer is planarized by chemical mechanical polishing (CMP) before forming the photoresist mask over the top inter-level-dielectric layer.

11. The method of claim 9, wherein the top inter-level-dielectric layer comprises an oxide layer formed with PECVD silicon oxide.

12. The method of claim 9, wherein the first removal process comprises a plasma etching process.

13. The method of claim 9, wherein the second removal process comprises a plasma etching process.

14. The method of claim 9, further comprising forming a plurality of color filters over the pixel array after the etch-stop layer and at least a portion of the inter-level-dielectric layer over the pixel array are removed.

15. The method of claim 14, further comprising forming a plurality of micro-lenses over the color filters.

16. The method of claim 9, further comprising forming an optically transparent nitride passivation layer overlying the top inter-level-dielectric layer.

17. A method for fabricating optical image sensors comprising:
forming a pixel array and a peripheral region surrounding the pixel array on a semiconductor substrate, said peripheral region containing peripheral circuitry;
forming a first inter-level-dielectric layer over the substrate;
forming a plurality of interconnect wiring layers over the first inter-level-dielectric layer, each interconnect wiring layer comprising interconnecting metal features, wherein N levels of interconnect wiring layers are provided over the peripheral region and 1 to (N−1) levels of interconnect wiring layers are provided over the pixel array, whereby the N levels of interconnect wiring layers over the peripheral region has a top-most level interconnecting metal features;
forming a top inter-level-dielectric layer over the top-most level interconnecting metal features;
forming an optical transparent passivation layer overlying the top inter-level-dielectric layer;
forming a photoresist mask over the top inter-level-dielectric layer and the optically transparent passivation layer wherein the photoresist mask covers the top inter-level-dielectric layer and the optically transparent passivation layer over the peripheral region and exposes the top inter-level-dielectric layer and the optical transparent passivation layer over the pixel array;
removing the top inter-level-dielectric layer and the optically transparent passivation layer and at least a portion of the interconnect wiring layers over the pixel array.

18. An optical image sensor device comprising:
a substrate;
a pixel array and a peripheral region formed on the substrate, said peripheral region containing peripheral circuitry;
an inter-level-dielectric layer over the pixel array and the peripheral region;
a plurality of interconnect wiring layers formed over the inter-level-dielectric layer, each interconnect wiring layer comprising interconnecting metal features, wherein N levels of interconnect wiring layers are provided over the peripheral region and 1 to (N−1) levels of interconnect wiring layers are provided over the pixel array.

19. The device of claim 18, wherein the interconnect wiring layers over the pixel array has a top-most level interconnect wiring layer, whose top surface that is lower over the pixel array than over the peripheral region by at least 100 nm.

20. The device of claim 19, wherein the top surface of the top-most level interconnect wiring layer over the pixel array is substantially planar.

21. The device of claim 18, further comprising a plurality of color filters provided over the pixel array region.

22. The device of claim 21, further comprising a plurality of micro-lenses provided over the color filters.

23. The device of claim 18, wherein the interconnect wiring layers over the peripheral region has a top-most level interconnect wiring layer and further comprising an etch-stop layer provided over the interconnecting metal features of the top-most level interconnect wiring layer.

24. The device of claim 23, wherein the etch-stop layer includes silicon nitride.

25. The device of claim 23, wherein thickness of the etch-stop layer is less than about 70 nm.

26. The device of claim 19, wherein the interconnect wiring layers over the peripheral region has a top-most level interconnect wiring layer and further comprising an etch-stop layer provided over the interconnecting metal features of the top-most level interconnect wiring layer.
